(19) United States
(12) Patent Application Publication
(10) Pub. No.: US 2023/0389331 A1
(43) Pub. Date: Nov. 30, 2023

(54) MEMORY CELL ISOLATION

(71) Applicant: Taiwan Semiconductor Manufacturing Company, Ltd., Hsinchu (TW)

(72) Inventors: Tzu-Yu Chen, Kaohsiung City (TW); Sheng-Hung Shih, Hsinchu (TW); Fu-Chen Chang, New Taipei City (TW); Kuo-Chi Tu, Hsinchu (TW)

(21) Appl. No.: 17/826,100

(22) Filed: May 26, 2022

(51) Int. Cl. H01L 27/11507

(52) U.S. Cl. CPC H01L 27/11507

(57) ABSTRACT

A semiconductor device is disclosed. The semiconductor device includes a semiconductor substrate, and a memory cell on the semiconductor substrate, where the memory cell includes a bottom contact, a memory material on the bottom contact, a top contact on the memory material, a first electrical isolation structure laterally surrounding the top contact, and a second electrical isolation structure laterally surrounding the memory material and the bottom contact.

### TECHNICAL FIELD

The subject matter described herein relates to electrical isolation of memory cells, and more particularly to isolation allowing for increased density.

### BACKGROUND

Semiconductor manufacturing processes include numerous fabrication steps or processes, each of which contributes to the formation of one or more semiconductor layers. Some layers are conductive and provide electrical connections between devices of an electronic system. Some layers may be formed, for example, by doping sections of a crystalline semiconductor substrate. In addition, one or more layers may be formed by adding, for example, conductive, resistive, and/or insulative layers on the crystalline semiconductor substrate.

Semiconductor arrangements are used in a multitude of electronic devices, such as mobile phones, laptops, desktops, tablets, watches, gaming systems, and various other industrial, commercial, and consumer electronics. Semiconductor arrangements generally comprise semiconductor portions and wiring portions formed inside the semiconductor portions.

### DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic illustration of a flowchart diagram illustrating a method of forming a semiconductor device according to some embodiments.

FIGS. 2-13 illustrates cross-sectional diagrams of a semiconductor device at various stages of the method of FIG. 1 according to some embodiments.

FIGS. 14-17 illustrate alternative memory cell structures which may be formed according to some embodiments.

When practical, similar reference numbers denote similar structures, features, or elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Several illustrative embodiments will now be described with respect to the accompanying drawings, which form a part hereof. The ensuing description provides embodiment(s) only and is not intended to limit the scope, applicability, or configuration of the disclosure. Rather, the ensuing description of the embodiment(s) will provide those skilled in the art with an enabling description for implementing one or more embodiments. It is understood that various changes may be made in the function and arrangement of elements without departing from the spirit and scope of this disclosure. In the following description, for the purposes of explanation, specific details are set forth in order to provide a thorough understanding of certain inventive embodiments. However, it will be apparent that various embodiments may be practiced without these specific details. The figures and description are not intended to be restrictive. The word “example” or “exemplary” is used herein to mean “serving as an example, instance, or illustration.” Any embodiment or design described herein as “exemplary” or “example” is not necessarily to be construed as preferred or advantageous over other embodiments or designs.

The stored memory state or the state to be written of a particular memory cell may be corrupted by read or write activity occurring in an adjacent memory cell. For example, the electrical signals used to implement read or write activity occurring in the adjacent memory cell can be capacitively coupled to the particular memory cell with sufficient effect that the stored memory state or the state being written to the particular memory cell may be corrupted.

The embodiments disclosed herein are examples of memory cell structures having improved electrical isolation. The improved electrical isolation reduces or eliminates the chance of memory state corruption due to electrical activity in an adjacent memory cell. Accordingly, memory cells with improved electrical isolation may be placed closer to one another to improve circuit density.

The features of the embodiments described herein may be applied to any type of memory. The particular embodiments illustrate a ferroelectric random-access memory (FeRAM). Ferroelectrics are a class of materials that consist of crystals exhibiting spontaneous electrical polarization. They can be in two states, which can be reversed with an external electric field. When such a field is applied, the electric dipoles formed in the crystal structure of the ferroelectric material tend to align themselves with the field direction. After the field is removed, they retain their polarization state—giving the material its non-volatile characteristic. A ferroelectric material has a non-linear relationship between the applied electric field and the polarization charge, giving the ferroelectric polarization-voltage (P-V) characteristic the form of a hysteresis loop.

FeRAM is generally referred to as a DRAM like memory with ferroelectrics implemented as dielectric in a capacitor part of the memory. In contrast with DRAM, FeRAM has lower power consumption, the potential for better performance, does not depend upon complex refresh circuitry, and is non-volatile. FeRAM memory cells typically include a transistor and a ferroelectric capacitor structure, which includes a ferroelectric structure sandwiched between a top electrode and a bottom electrode. The FeRAM memory cell is configured to store a bit of data, depending on how atoms are aligned relative to one another in the ferroelectric capacitor structure. For example, a first state of a FeRAM memory cell in which atoms in the ferroelectric structure are polarized in an “up” direction may represent a binary value of “1”, whereas a second state of the FeRAM memory cell in which atoms in the ferroelectric structure are polarized in a “down” direction may represent a binary value of “0”, or vice versa.

Discovery of a ferroelectric phase in hafnium-oxide (HfO2) has triggered some new ideas in manufacturing memory devices comprising FeRAM. It has been discovered that an orthorhombic crystal phase—the ferroelectric phase—that can be stabilized by doping HfO2 with e.g. silicon (Si). Compared to PZT, HfO2 has a lower dielectric constant and can be deposited in thin layers, in a conformal way. On top of that, HfO2 is material that has been used as the gate stack dielectric material in logic devices.

In accordance with the present disclosure, a novel process for manufacturing devices is provided. In some embodiments, fabrication of the memory device includes fabricating one or more of a FeRAM cell. The FeRAM cell, in those embodiments, may be a multi-bit cell sharing common plate lines (ground lines, “PL” herein-after). The sharing of the common PL by the multi-bit FeRAM cell in those embodiments improves dimension density of memory devices when they are stacked 3D during manufacturing, improves memory device performance and/or provides any other benefits.

The figures illustrate an example process of manufacturing an example memory device including a FeRAM cell in accordance with the present disclosure. In these figures, to simplify the drawings, common elements are identified with the same reference numerals. Further, for intermediate device structures in successive processing stages of the example process, reference numerals are only used to mark changes from the previous stage, unless otherwise noted. It should be understood, although only one or two FeRAM cells are illustrated in these figures, it is not intended to limit the present disclosure only to a memory device having only one or two FeRAM cells. It is understood that a memory device in accordance with the present disclosure can have more than one or two FeRAM cells.

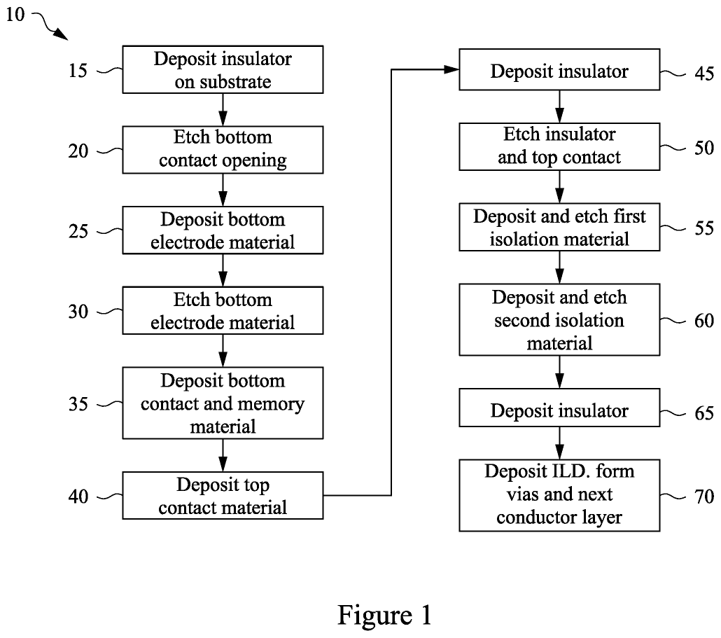

FIG. 1 is a schematic illustration of a flowchart diagram illustrating a method 10 of forming a semiconductor device. The semiconductor device includes adjacent memory cells in a memory area of a semiconductor substrate formed between conductor layers in a back end of line (BEOL) interconnect formation process. The semiconductor device also includes via connections to the memory cells, and via connections between conductor layers in another area of the semiconductor substrate.

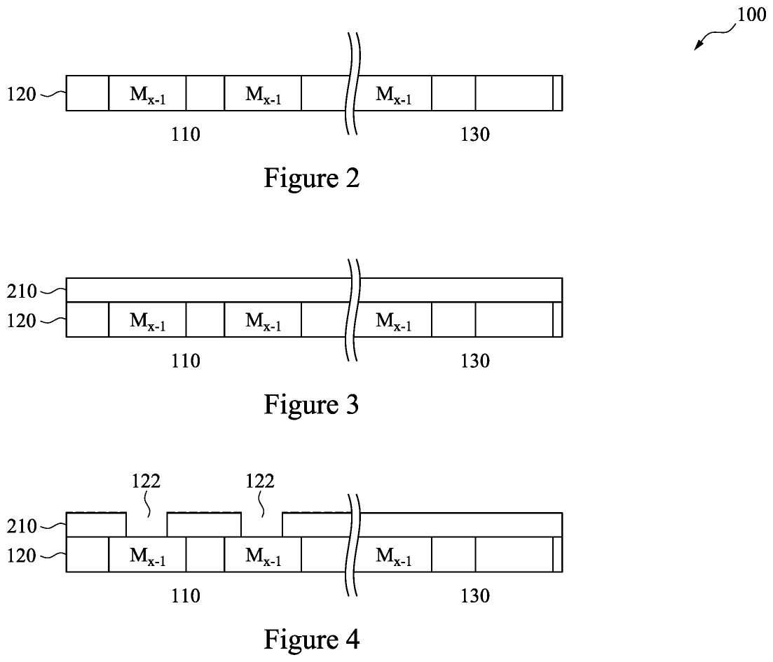

FIG. 2 illustrates a cross-sectional diagram of a semiconductor substrate 100, which includes a plurality of functional areas fabricated on a single substrate. Semiconductor substrate 100 includes a first area 110 and a second area 130. First area 110 may include circuitry (not shown) formed on the semiconductor substrate 100, such as semiconductor structures for processing signals received from or transmitted to, for example, second area 130, another area, or another system or chip. Second area 130 also includes circuitry (not shown) formed on the semiconductor substrate 100, such as semiconductor structures for processing signals received from or transmitted to, for example, first area 110, another area, or another system or chip.

The semiconductor substrate 100 may have other areas, which include circuitry (not shown) formed on the semiconductor substrate 100, such as semiconductor structures for processing signals received from or transmitted to, for example, first area 110, second area 130, another area, or another system or chip.

The semiconductor substrate 100 also includes metallization layers and vias. As depicted, semiconductor substrate 100 is fabricated to have a metallization layer Mx-1 formed in an interlayer dielectric 120. Metallization layer Mx-1 may be electrically connected to circuitry formed on the semiconductor substrate 100, for example, in first and second areas 110 and 130. Other embodiments may contain additional metallization layers and additional vias.

FIG. 3 illustrates semiconductor substrate 100 after block 15 of method 10 of FIG. 1. As shown, FIG. 3 illustrates semiconductor substrate 100, over which an insulator layer 210, comprising, for example, silicon carbide, or other similar, has been formed in first and second areas 110 and 130. In some embodiments, the insulator layer 210 can include a dielectric material with a dielectric constant (k-value) higher than about 2.5.

In some embodiments, the insulator layer 210 can include (i) silicon carbide, silicon oxide, silicon nitride, and/or silicon oxynitride, or another suitable dielectric material, (ii) a high-k dielectric material, such as hafnium oxide (HfO₂), TiO₂, HfZrO, Ta₂O₃, HfSiO₄, ZrO₂, ZrSiO₂, (iii) a high-k dielectric material having oxides or nitrides of Li, Be, Mg, Ca, Sr, Sc, Y, Zr, Al, La, Ce, Pr, Nd, Sm, Eu, Gd, Tb, Dy, Ho, Er, Tm, Yb, or Lu, or another suitable dielectric material, or (iv) a combination thereof.

In some embodiments, the insulator layer 210 is formed by one or more of chemical vapor deposition (CVD), a variety of suitable processes including CVD, low pressure CVD (LPCVD), plasma-enhanced CVD (PECVD), and atomic layer deposition (ALD). In some embodiments, other suitable processes may be used to form the insulator layer 210.

The insulator layer 210 may, for example, have a thickness equal to about 10 A, about 25 A, about 50 A, about 75 A, about 100 A, about 200 A, about 300 A, about 400 A, about 500 A, about 600 A, about 700 A, about 800 A, about 900 A, about 1000 A, about 1100 A, about 1200 A, about 1300 A, about 1400 A, or about 1500 A. In some embodiments, the insulator layer 210 has another thickness.

FIG. 4 illustrates semiconductor substrate 100 after block 20 of method 10 of FIG. 1. As shown, FIG. 4 illustrates semiconductor substrate 100, where bottom contact openings 122 have been formed in first area 110, for example, using a photolithographic etching process. In some embodiments, the etching process may include a plasma-induced etching process, a wet etch process, or another etching process known to those of skill in the art.

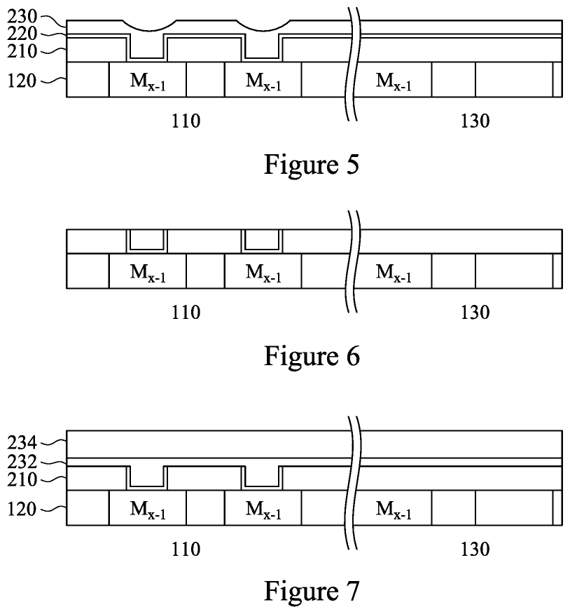

FIG. 5 illustrates semiconductor substrate 100 after block 25 of method 10 of FIG. 1. As shown, FIG. 5 illustrates semiconductor substrate 100, where barrier layer 220 and bottom electrode 230 have been formed in first and second areas 110 and 130.

A barrier layer 220 is formed over the insulator layer 210, such that the barrier layer 220 contacts the fourth metallization layer Mx-1 through the hole etched in the insulator layer 210 at 20 of method 10. The barrier layer 220 is conductive, and is configured to substantially prevent the metal material of fourth metallization layer Mx-1, such as copper, from diffusing or migrating therethrough. In some embodiments, the barrier layer 220 may, for example, be formed so as to include one or more of Ta, TaN, and TiN. In some embodiments, other materials may be used. The barrier layer 220 may, for example, have a thickness equal to about 10 A, about 25 A, about 50 A, about 75 A, about 100 A, about 200 A, about 300 A, about 400 A, about 500 A, about 600 A, about 700 A, about 800 A, about 900 A, or about 1000 A. In some embodiments, the barrier layer 220 has another thickness. In some embodiments, the barrier layer 220 is formed by one or more of chemical vapor deposition (CVD), a variety of suitable processes including CVD, low pressure CVD (LPCVD), plasma-enhanced CVD (PECVD), and atomic layer deposition (ALD). In some embodiments, other suitable processes may be used to form the barrier layer 220.

A bottom electrode 230 is also formed over the barrier layer 220, where the bottom electrode 230 mechanically and electrically contacts the barrier layer 220, as illustrated in FIG. 5. The bottom electrode 230 is conductive, and may, for example, be formed so as to include one or more of Cu, Ag, Pt, Au, W, Ti, TiN, TaN, Ru, and Mo. In some embodiments, other materials may be used. The bottom electrode 230 may, for example, have a thickness equal to about 10 A, about 25 A, about 50 A, about 75 A, about 100 A, about 200 A, about 300 A, about 400 A, about 500 A, about 600 A, about 700 A, about 800 A, about 900 A, or about 1000 A. In some embodiments, the bottom electrode 230 has another thickness. In some embodiments, the bottom electrode 230 is formed by one or more of chemical vapor deposition (CVD), a variety of suitable processes including CVD, low pressure CVD (LPCVD), plasma-enhanced CVD (PECVD), and atomic layer deposition (ALD). In some embodiments, other suitable processes may be used to form the bottom electrode 230.

FIG. 6 illustrates semiconductor substrate 100 after block 30 of method 10 of FIG. 1. As shown, FIG. 5 illustrates semiconductor substrate 100, where barrier layer 220 and bottom electrode 230 have been etched in first and second areas 110 and 130.

In some embodiments, the etching process may include a plasma-induced etching process, a wet etch process, or another etching process known to those of skill in the art. In some embodiments, the etching process may include a planarization process, such as chemo-mechanical planarization (CMP).

FIG. 7 illustrates semiconductor substrate 100 after block 35 of method 10 of FIG. 1. As shown, FIG. 7 illustrates semiconductor substrate 100, where bottom contact 232 and memory material 234 have been formed in first and second areas 110 and 130.

A bottom contact 232 is formed over the insulator layer 210 and the bottom electrode 230, where the bottom contact 232 mechanically and electrically contacts the bottom electrode 230, as illustrated in FIG. 7. The bottom contact 232 is conductive, and may, for example, be formed so as to include one or more of Cu, Ag, Pt, Au, W, Ti, TiN, TaN, Ru, and Mo. In some embodiments, other materials may be used. The bottom contact 232 may, for example, have a thickness equal to about 10 A, about 25 A, about 50 A, about 75 A, about 100 A, about 200 A, about 300 A, about 400 A, about 500 A, about 600 A, about 700 A, about 800 A, about 900 A, or about 1000 A. In some embodiments, the bottom contact 232 has another thickness. In some embodiments, the bottom contact 232 is formed by one or more of chemical vapor deposition (CVD), a variety of suitable processes including CVD, low pressure CVD (LPCVD), plasma-enhanced CVD (PECVD), and atomic layer deposition (ALD). In some embodiments, other suitable processes may be used to form the bottom contact 232.

A memory material 234 is formed over the bottom contact 232, where the memory material mechanically and electrically contacts the bottom contact 232, as illustrated in FIG. 7. The memory material may include a ferroelectric dielectric material, such as hafnium oxide (HfO₂), TiO₂, HfZrO, Ta₂O₃, HfSiO₄, ZrO₂, ZrSiO₂, or another suitable ferroelectric material. However, it is understood that the temperature range is only cited as examples, and variations can be made depending on the applications. In some embodiments, the memory material 234 may, for example, have a thickness equal to about 10 A, about 25 A, about 50 A, about 75 A, about 100 A, about 200 A, about 300 A, about 400 A, about 500 A, about 600 A, about 700 A, about 800 A, about 900 A, or about 1000 A. In some embodiments, the memory material 234 may be formed by an ALD and/or one or more other suitable methods. In some embodiments, the gate dielectric layer can be formed with ALD using hafnium chloride (HfCl₄) as a precursor at a temperature ranging from about 250° C. to about 350° C. In some embodiments, the memory material 234 may be formed by one or more of chemical vapor deposition (CVD), a variety of suitable processes including CVD, low pressure CVD (LPCVD), plasma-enhanced CVD (PECVD). In some embodiments, the memory material 234 can have a thickness ranging from about 1 nm to about 3 nm. However, it is understood that the thickness range are only cited as examples, and variations can be made depending on the applications and deposition processes.

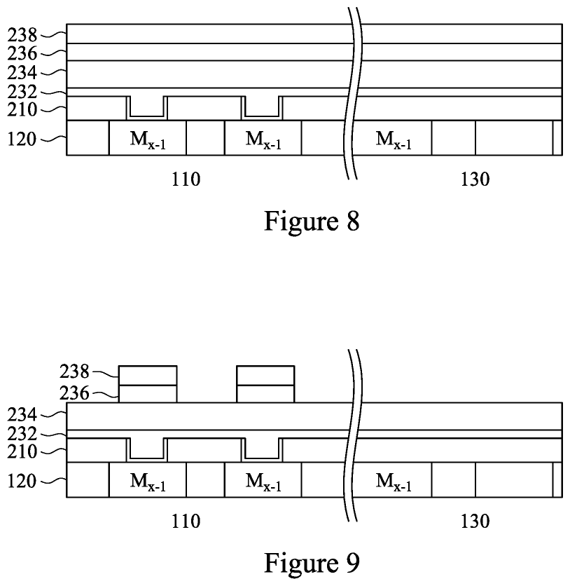

FIG. 8 illustrates semiconductor substrate 100 after blocks 40 and 45 of method 10 of FIG. 1. As shown, FIG. 8 illustrates semiconductor substrate 100, where top contact 236 and dielectric material 238 have been formed over the memory material 234 in first and second areas 110 and 130.

A top contact 236 is formed over the memory material 234, where the top contact 236 mechanically and electrically contacts the memory material 234, as illustrated in FIG. 8. The top contact 236 is conductive, and may, for example, be formed so as to include one or more of Cu, Ag, Pt, Au, W, Ti, TiN, TaN, Ru, and Mo. In some embodiments, other materials may be used. The top contact 236 may, for example, have a thickness equal to about 10 A, about 25 A, about 50 A, about 75 A, about 100 A, about 200 A, about 300 A, about 400 A, about 500 A, about 600 A, about 700 A, about 800 A, about 900 A, or about 1000 A. In some embodiments, the top contact 236 has another thickness. In some embodiments, the top contact 236 is formed by one or more of chemical vapor deposition (CVD), a variety of suitable processes including CVD, low pressure CVD (LPCVD), plasma-enhanced CVD (PECVD), and atomic layer deposition (ALD). In some embodiments, other suitable processes may be used to form the top contact 236.

A dielectric material 238 is formed over the top contact 236, where the dielectric material 238 mechanically and electrically contacts the top contact 236, as illustrated in FIG. 8. The dielectric material may comprise one or more layers may include silicon oxide (SiO₂), silicon nitride (e.g. SiN or Si₃N₄), silicon oxynitride (SiON), silicon carbon nitride (SiCN), silicon oxycarbide nitride (SiOCN), silicon oxycarbide (SiOC), or a combination thereof. In some embodiments, the dielectric material 238 is formed by one or more of chemical vapor deposition (CVD), a variety of suitable processes including CVD, low pressure CVD (LPCVD), plasma-enhanced CVD (PECVD), and atomic layer deposition (ALD). In some embodiments, other suitable processes may be used to form the dielectric material 238. The dielectric material 238 may, for example, have a thickness equal to about 10 A, about 25 A, about 50 A, about 75 A, about 100 A, about 200 A, about 300 A, about 400 A, about 500 A, about 600 A, about 700 A, about 800 A, about 900 A, about 1000 A, about 1100 A, about 1200 A, about 1300 A, about 1400 A, or about 1500 A. In some embodiments, the dielectric material 238 has another thickness.

FIG. 9 illustrates semiconductor substrate 100 after block 50 of method 10 of FIG. 1. As shown, FIG. 9 illustrates semiconductor substrate 100, where top contact 236 and dielectric material 238 have been formed, for example, using a photolithographic etching process. In some embodiments, the etching process may include a plasma-induced etching process, a wet etch process, or another etching process known to those of skill in the art.

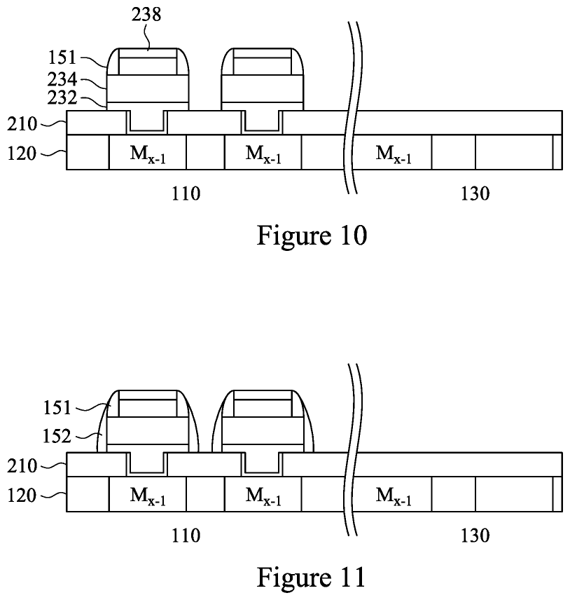

FIG. 10 illustrates semiconductor substrate 100 after block 55 of method 10 of FIG. 1. As shown, FIG. 10 illustrates semiconductor substrate 100, where first spacers 151 have been formed, and where bottom contact 232 and memory material 234 have been etched, for example, using a photolithographic etching process. In some embodiments, the etching process may include a plasma-induced etching process, a wet etch process, or another etching process known to those of skill in the art. The first spacers form electrical isolation structures which laterally surround the top contacts 236 of the adjacent memory cells and electrically isolate the adjacent memory cells being formed in first area 110.

In some embodiments, the first spacers 151 may be formed by conformally depositing one or more first spacer layers (not shown) on the dielectric material 238 and the memory material 234, and along the sidewalls of the dielectric material 238 and top contact 236. The first spacer layers may be made of different materials and have different thicknesses than each other. The one or more first spacer layers may include silicon oxide (SiO₂), silicon nitride (e.g. SiN or Si₃N₄), silicon oxynitride (SiON), silicon carbon nitride (SiCN), silicon oxycarbide nitride (SiOCN), silicon oxycarbide (SiOC), or a combination thereof. In some embodiments, the one or more first spacer layers may include a dielectric material with a dielectric constant (k-value) higher than about 2.5.

The one or more first spacer layers may be deposited by one or more of chemical vapor deposition (CVD), a variety of suitable processes including CVD, low pressure CVD (LPCVD), plasma-enhanced CVD (PECVD), and atomic layer deposition (ALD). In some embodiments, other suitable processes may be used to form the first spacer layers.

In some embodiments, the one or more first spacer layers may be subsequently anisotropically etched to form the first spacers 151. The etching process may include a RIE, NBE, or other etching processes. In some embodiments, the etching process used to etch the first spacer layers to form the first spacers 151 may also be used to, for example, substantially simultaneously etch the bottom contact 232 and memory material 234. In some embodiments, the etching process may include a planarization process, such as chemo-mechanical planarization (CMP).

FIG. 11 illustrates semiconductor substrate 100 after block 60 of method 10 of FIG. 1. As shown, FIG. 11 illustrates semiconductor substrate 100, where second spacers 152 have been formed. The second spacers 152 form electrical isolation structures which laterally surround the memory materials 234 and the bottom contacts 232 of the adjacent memory cells and electrically isolate the adjacent memory cells being formed in first area 110.

In some embodiments, the second spacers 152 may be formed by conformally depositing one or more second spacer layers (not shown) on the dielectric material 238 and the insulator layer 210, and along the sidewalls of the first spacers 151, the memory material 234, and the bottom contact 232. The second spacer layers may be made of different materials and have different thicknesses than each other. The one or more second spacer layers may include silicon oxide (SiO₂), silicon nitride (e.g. SiN or Si₃N₄), silicon oxynitride (SiON), silicon carbon nitride (SiCN), silicon oxycarbide nitride (SiOCN), silicon oxycarbide (SiOC), or a combination thereof. In some embodiments, the one or more second spacer layers may include a dielectric material with a dielectric constant (k-value) higher than about 2.5.

The one or more second spacer layers may be deposited by one or more of chemical vapor deposition (CVD), a variety of suitable processes including CVD, low pressure CVD (LPCVD), plasma-enhanced CVD (PECVD), and atomic layer deposition (ALD). In some embodiments, other suitable processes may be used to form the second spacer layers.

In some embodiments, the one or more second spacer layers may be subsequently anisotropically etched to form the second spacers 152. The etching process may include a RIE, NBE, or other etching processes. In some embodiments, the etching process may include a planarization process, such as chemo-mechanical planarization (CMP).

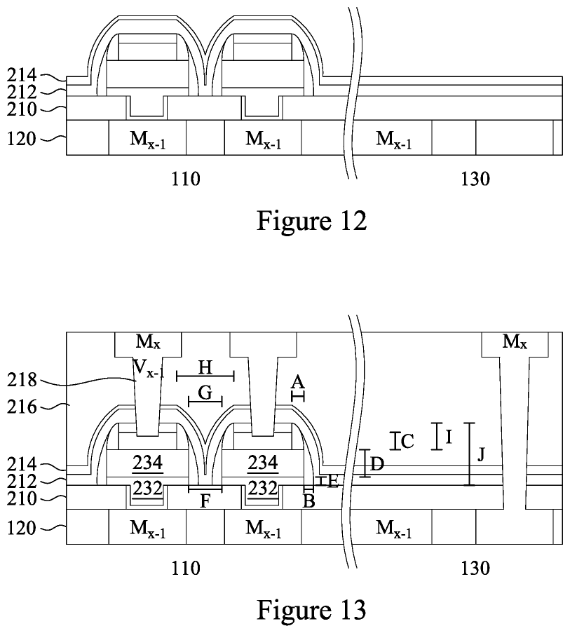

FIG. 12 illustrates semiconductor substrate 100 after block of method 65 of FIG. 1. As shown, FIG. 12 illustrates semiconductor substrate 100, over which an insulator layers 212 and 214 formed in first and second areas 110 and 130. In some embodiments, insulator layer 212 includes, for example, silicon carbide, or other similar. In some embodiments, insulator layer 214 includes, for example, Tetraethyl orthosilicate (TEOS), or other similar. In some embodiments, the insulator layers 212 and 214 can each include a dielectric material with a dielectric constant (k-value) higher than about 2.5.

In some embodiments, the insulator layer 212 can include (i) silicon carbide, silicon oxide, silicon nitride, and/or silicon oxynitride, or another suitable dielectric material, (ii) a high-k dielectric material, such as hafnium oxide (HfO₂), TiO₂, HfZrO, Ta₂O₃, HfSiO₄, ZrO₂, ZrSiO₂, (iii) a high-k dielectric material having oxides or nitrides of Li, Be, Mg, Ca, Sr, Sc, Y, Zr, Al, La, Ce, Pr, Nd, Sm, Eu, Gd, Tb, Dy, Ho, Er, Tm, Yb, or Lu, or another suitable dielectric material, or (iv) a combination thereof.

In some embodiments, the insulator layer 212 is formed by one or more of chemical vapor deposition (CVD), a variety of suitable processes including CVD, low pressure CVD (LPCVD), plasma-enhanced CVD (PECVD), and atomic layer deposition (ALD). In some embodiments, other suitable processes may be used to form the insulator layer 212.

The insulator layer 212 may, for example, have a thickness equal to about 10 A, about 25 A, about 50 A, about 75 A, about 100 A, about 200 A, about 300 A, about 400 A, about 500 A, about 600 A, about 700 A, about 800 A, about 900 A, about 1000 A, about 1100 A, about 1200 A, about 1300 A, about 1400 A, or about 1500 A. In some embodiments, the insulator layer 212 has another thickness.

In some embodiments, the insulator layer 214 includes silicon oxide, carbon-containing oxide such as silicon oxycarbide (SiOC), silicate glass, tetraethylorthosilicate (TEOS) oxide, un-doped silicate glass, or doped silicon oxide such as borophosphosilicate glass (BPSG), fluorine-doped silica glass (FSG), phosphosilicate glass (PSG), boron doped silicon glass (BSG), combinations thereof and/or other suitable dielectric materials. In some embodiments, the insulator layer 214 may include low-k dielectric material with a dielectric constant lower than 4, or extreme low-k (ELK) dielectric material with a dielectric constant lower than 2.5. In some embodiments, the low-k material includes a polymer-based material, such as benzocyclobutene (BCB), FLARE®, or SILK®; or a silicon dioxide-based material, such as hydrogen silsesquioxane (HSQ) or SiOF. The insulator layer 214 may be a single layer structure or a multi-layer structure. The insulator layer 214 may be formed, for example, by CVD, PECVD, FCVD, spin coating, or the like.

FIG. 13 illustrates semiconductor substrate 100 after block of method 70 of FIG. 1. As shown, FIG. 13 illustrates semiconductor substrate 100, over which an ILD 216, a via layer 218, and metallization layer Mx are formed in first and second areas 110 and 130.

As illustrated, semiconductor substrate 100 is fabricated to have via layer 218 and metallization layer Mx formed in ILD 216. The illustrated portions of metallization layer Mx in first area 110 are electrically connected to the top contacts 236 by vias 218 and may be electrically connected to circuitry formed on the semiconductor substrate 100, for example, in at least one of first and second areas 110 and 130, and another area on the semiconductor substrate 100. The illustrated portion of metallization layer Mx in second area 130 is electrically connected to the illustrated portion of metallization layer Mx-1 in second area 130, and may be electrically connected to circuitry formed on the semiconductor substrate 100, for example, in at least one of first and second areas 110 and 130, and another area on the semiconductor substrate 100. Other embodiments may contain additional metallization layers and additional vias, as understood by those of skill in the art.

The ILD 216 may provide electrical insulation as well as structural support for the various features of semiconductor substrate 100 during many fabrication process steps and afterwards.

The ILD 216 for the first and second areas 110 and 130 may be simultaneously formed. Similarly, the metallization layer Mx for the first and second areas 110 and 130 may be simultaneously formed. And the vias 218 for the first and second areas 110 and 130 may be simultaneously formed.

In some embodiments, the portions of each of metallization layers Mx-1 and Mx extend beyond the vias 218 connected thereto by no more than a minimum distance as defined by process design rules.

In some embodiments, the illustrated portions of metallization layer Mx-1 are not directly electrically shorted, are not directly electrically connected, and/or are not directly connected to the illustrated conductors with connections other than those illustrated in FIG. 13. In some embodiments, the illustrated portions of metallization layer Mx are not directly electrically shorted, are not directly electrically connected, and/or are not directly connected to the illustrated conductors with connections other than those illustrated in FIG. 13.

As, for example, illustrated in FIG. 13, for any particular line segment in the illustrated plane starting on one of the memory material sections 234 and ending on the other of the memory material sections 234 intersects first and second continuous portions of second spacers 152, first and second continuous portions of insulator layer 212, and exactly one continuous portion of insulator layer 214. Similarly, for any particular line segment in the illustrated plane starting on one of the memory material sections 234 and ending on the other of the memory material sections 234 intersects only materials having a dielectric constant greater than 2.5. Similarly, for any particular line segment in the illustrated plane starting on one of the memory material sections 234 and ending on the other of the memory material sections 234 does not intersect the ILD 216.

As, for example, illustrated in FIG. 13, for any particular line segment in the illustrated plane starting on one of the bottom contacts 232 and ending on the other of the bottom contacts 232 intersects first and second continuous portions of second spacers 152, first and second continuous portions of insulator layer 212, and exactly one continuous portion of insulator layer 214. Similarly, for any particular line segment in the illustrated plane starting on one of the bottom contacts 232 and ending on the other of the bottom contacts 232 intersects only materials having a dielectric constant greater than 2.5. Similarly, for any particular line segment in the illustrated plane starting on one of the bottom contacts 232 and ending on the other of the bottom contacts 232 does not intersect the ILD 216.

FIG. 13 illustrates certain embodiments of dimensions. Dimension A is the lateral width of the first spacers 151, dimension B is the lateral width of the second spacers 152, dimension C is the vertical height of top contacts 236, dimension D is the vertical height of memory materials 234, dimension E is the vertical height of bottom contacts 232, dimension I is the vertical height of first spacers 151, dimension J is the vertical height of second spacers 152, dimension F is the lateral width of a gap between the adjacent bottom contacts 232, dimension G is the lateral width of a gap between the adjacent memory materials 234, dimension H is the lateral width of a gap between the adjacent top contacts 236.

In some embodiments, the value of dimension A is equal to about 50 A, about 100 A, about 150 A, about 2050 A, about 250 A, about 300 A, about 350 A, about 400 A, about 450 A, about 500 A, about 600 A, about 750 A, about 1000 A, or about 1250 A. Other values of dimension A may be used.

In some embodiments, the value of dimension B is equal to about 25 A, about 50 A, about 100 A, about 150 A, about 2050 A, about 250 A, about 300 A, about 350 A, about 400 A, about 450 A, about 500 A, about 600 A, about 750 A, about 1000 A, or about 1250 A. Other values of dimension B may be used.

In some embodiments, the value of dimension C is equal to about 10 A, about 25 A, about 50 A, about 75 A, about 100 A, about 200 A, about 300 A, about 400 A, about 500 A, about 600 A, about 700 A, about 800 A, about 900 A, or about 1000 A. Other values of dimension C may be used.

In some embodiments, the value of dimension D is equal to about 10 A, about 25 A, about 50 A, about 75 A, about 100 A, about 200 A, about 300 A, about 400 A, about 500 A, about 600 A, about 700 A, about 800 A, about 900 A, about 1000 A, about 1100 A, about 1200 A, about 1300 A, about 1400 A, about 1500 A, about 1600 A, about 1700 A, about 1800 A, about 1900 A, or about 2000 A. Other values of dimension D may be used.

In some embodiments, the value of dimension E is equal to about 10 A, about 25 A, about 50 A, about 75 A, about 100 A, about 200 A, about 300 A, about 400 A, about 500 A, about 600 A, about 700 A, about 800 A, about 900 A, or about 1000 A. Other values of dimension E may be used.

In some embodiments, the value of dimension F is equal to about 100 A, about 150 A, about 200 A, about 250 A, about 300 A, about 350 A, about 400 A, about 450 A, about 500 A, about 600 A, about 700 A, about 800 A, about 900 A, or about 1000 A. Other values of dimension F may be used.

In some embodiments, the value of dimension G is equal to about 100 A, about 150 A, about 200 A, about 250 A, about 300 A, about 350 A, about 400 A, about 450 A, about 500 A, about 600 A, about 700 A, about 800 A, about 900 A, or about 1000 A. Other values of dimension G may be used.

In some embodiments, the value of dimension H is equal to about 100 A, about 150 A, about 200 A, about 250 A, about 300 A, about 350 A, about 400 A, about 450 A, about 500 A, about 600 A, about 700 A, about 800 A, about 900 A, or about 1000 A. Other values of dimension H may be used.

In some embodiments, the value of dimension I is equal to about 100 A, about 150 A, about 200 A, about 250 A, about 300 A, about 350 A, about 400 A, about 450 A, about 500 A, about 600 A, about 700 A, about 800 A, about 900 A, or about 1000 A. Other values of dimension I may be used.

In some embodiments, the value of dimension J is equal to about 100 A, about 150 A, about 200 A, about 250 A, about 300 A, about 350 A, about 400 A, about 450 A, about 500 A, about 600 A, about 650 A, about 700 A, about 800 A, about 900 A, about 1000 A, about 1100 A, about 1200 A, about 1300 A, about 1400 A, about 1500 A, about 1600 A, about 1700 A, about 1800 A, about 1900 A, or about 2000 A. Other values of dimension J may be used.

In some embodiments, dimension A is greater than dimension B. In some embodiments, dimension A is less than dimension B. In some embodiments, dimension A is substantially equal to dimension B.

In some embodiments, dimension F is greater than dimension G. In some embodiments, dimension F is less than dimension G. In some embodiments, dimension F is substantially equal to dimension G.

In some embodiments, dimension F is greater than dimension H. In some embodiments, dimension F is less than dimension H. In some embodiments, dimension F is substantially equal to dimension H.

In some embodiments, dimension H is greater than dimension G. In some embodiments, dimension H is less than dimension G. In some embodiments, dimension H is substantially equal to dimension G.

In some embodiments, because of the use of materials having relatively high dielectric constant in the gap between the adjacent bottom contacts 232, the ratio of dimension E to dimension F may be greater than about 1, about 2, about 3, about 4, about 5, about 6, about 7, about 8, about 9, about 10, about 12, about 15, about 20, about 25, about 30, about 35, about 40, about 45, or about 50 without allowing electrical signals used to implement read or write activity occurring in one memory cell to capacitively coupled to the adjacent memory cell with sufficient effect that the stored memory state or the state being written to the adjacent memory cell is corrupted. Accordingly, memory cells with the improved electrical isolation may be placed closer to one another to improve circuit density.

In some embodiments, because of the use of materials having relatively high dielectric constant in the gap between the adjacent memory materials 234, the ratio of dimension D to dimension G may be greater than about 1, about 2, about 3, about 4, about 5, about 6, about 7, about 8, about 9, about 10, about 12, about 15, about 20, about 25, about 30, about 35, about 40, about 45, or about 50 without allowing electrical signals used to implement read or write activity occurring in one memory cell to capacitively coupled to the adjacent memory cell with sufficient effect that the stored memory state or the state being written to the adjacent memory cell is corrupted. Accordingly, memory cells with the improved electrical isolation may be placed closer to one another to improve circuit density.

In some embodiments, because of the use of materials having relatively high dielectric constant in the gap between the adjacent top contacts 236, the ratio of dimension C to dimension H may be greater than about 1, about 2, about 3, about 4, about 5, about 6, about 7, about 8, about 9, about 10, about 12, about 15, about 20, about 25, about 30, about 35, about 40, about 45, or about 50 without allowing electrical signals used to implement read or write activity occurring in one memory cell to capacitively coupled to the adjacent memory cell with sufficient effect that the stored memory state or the state being written to the adjacent memory cell is corrupted. Accordingly, memory cells with the improved electrical isolation may be placed closer to one another to improve circuit density.

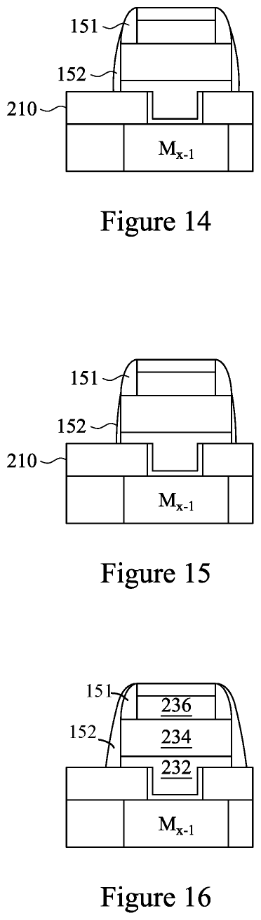

FIG. 14 illustrates an alternative embodiment of a memory cell structure which may be used instead of the corresponding memory cell structure illustrated in FIG. 13. As shown, the second spacer 152 extends from insulator layer 210 to a point along the first spacer 151 which is between points of the first spacer 151 nearest to and farthest from insulator layer 210. In some embodiments, the second spacer 152 extends from insulator layer 210 to a point along the first spacer 151 which is about half way between points of the first spacer 151 nearest to and farthest from insulator layer 210. The point along the first spacer 151 to which layer second spacer 152 extends can be controlled, for example, by varying an etch time of second spacer 152. The illustrated structure can be manufactured using photolithographic deposition and etching processes known to those of skill in the art. For example, the photolithographic deposition and etching processes discussed above may be used and readily modified, as necessary, to manufacture the embodiment of FIG. 14, as understood by those of skill in the art.

FIG. 15 illustrates an alternative embodiment of a memory cell structure which may be used instead of the corresponding memory cell structure illustrated in FIG. 13. As shown, the second spacer 152 extends from insulator layer 210 to about a point of the first spacer 151 nearest to insulator layer 210. The point along the first spacer 151 to which layer second spacer 152 extends can be controlled, for example, by varying an etch time of second spacer 152. The illustrated structure can be manufactured using photolithographic deposition and etching processes known to those of skill in the art. For example, the photolithographic deposition and etching processes discussed above may be used and readily modified, as necessary, to manufacture the embodiment of FIG. 15, as understood by those of skill in the art.

FIG. 16 illustrates an alternative embodiment of a memory cell structure which may be used instead of the corresponding memory cell structure illustrated in FIG. 13. As shown, the memory material 234 has a lateral width substantially equal to the lateral width of top contact 236, and which is less than the lateral width of bottom contact 232. This structure can be manufactured using photolithographic deposition and etching processes known to those of skill in the art. For example, the photolithographic deposition and etching processes discussed above may be used and readily modified, as necessary, to manufacture the embodiment of FIG. 16, as understood by those of skill in the art.

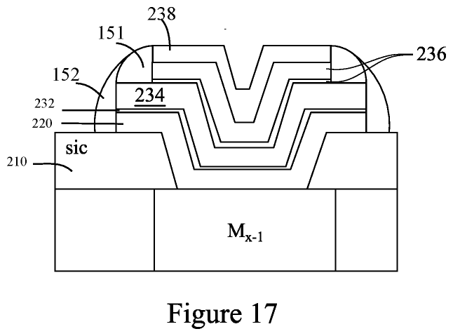

FIG. 17 illustrates an alternative embodiment of a memory cell structure which may be used instead of the corresponding memory cell structure illustrated in FIG. 13. As shown, the top contact 236 has multiple conductive layers. In some embodiments, the multiple conductive layers are formed of a same material. In some embodiments, the materials of the multiple conductive layers are different. In addition, in this embodiment, bottom contact 232 is conformally formed on barrier layer 220. This structure can be manufactured using photolithographic deposition and etching processes known to those of skill in the art. For example, the photolithographic deposition and etching processes discussed above may be used and readily modified, as necessary, to manufacture the embodiment of FIG. 17, as understood by those of skill in the art.

As discussed in further detail above, the use of higher k dielectric materials between adjacent memory cells provides improved electrical isolation between the adjacent memory cells. In some embodiments, the use of higher k dielectric materials between adjacent memory cells allows for closer placement of the adjacent memory cells, resulting in improved circuit density.

The individual features of each embodiment may be practiced by forming the individual features with features of the other embodiments using the photolithographic deposition and etching processes discussed above, where the processes are readily modified, as necessary.

One inventive aspect is a semiconductor device. The semiconductor device includes a semiconductor substrate, and a memory cell on the semiconductor substrate, where the memory cell includes a bottom contact, a memory material on the bottom contact, a top contact on the memory material, a first electrical isolation structure laterally surrounding the top contact, and a second electrical isolation structure, distinct from the first electrical isolation structure, laterally surrounding the memory material and the bottom contact.

In some embodiments, the first electrical isolation structure has a first material, the second electrical isolation structure has a second material, and the first and second materials are different.

In some embodiments, the first electrical isolation structure has a first material, where the second electrical isolation structure has a second material, and the first and second materials are the same.

In some embodiments, the memory material includes a ferroelectric material.

In some embodiments, the second electrical isolation structure extends substantially to a point along the first electrical isolation structure which is farthest from the semiconductor substrate.

In some embodiments, the second electrical isolation structure extends substantially to a point along the first electrical isolation structure which is nearest to the semiconductor substrate.

In some embodiments, the second electrical isolation structure extends substantially to a point along the first electrical isolation structure which is about half way between points of the first electrical isolation structure nearest to and farthest from the semiconductor substrate.

Another inventive aspect is a semiconductor device. The semiconductor device includes a semiconductor substrate, and a memory cell on the semiconductor substrate, where the memory cell includes a bottom contact, a memory material on the bottom contact, a top contact on the memory material, and a first electrical isolation structure laterally surrounding the memory material, the bottom contact, and at least a portion of the top contact.

In some embodiments, the semiconductor device includes a second electrical isolation structure laterally surrounding at least a portion of the top contact, where the first electrical isolation structure has a first material, where the second electrical isolation structure has a second material, and the first and second materials are different.

In some embodiments, the semiconductor device includes a second electrical isolation structure laterally surrounding at least a portion of the top contact, where the first electrical isolation structure has a first material, where the second electrical isolation structure has a second material, and the first and second materials are the same.

In some embodiments, the memory material includes a ferroelectric material.

In some embodiments, the semiconductor device includes a second electrical isolation structure laterally surrounding at least a portion of the top contact, where the first electrical isolation structure extends substantially to a point along the second electrical isolation structure which is farthest from the semiconductor substrate.

In some embodiments, the semiconductor device includes a second electrical isolation structure laterally surrounding at least a portion of the top contact, where the first electrical isolation structure extends substantially to a point along the second electrical isolation structure which is nearest to the semiconductor substrate.

In some embodiments, the semiconductor device includes a second electrical isolation structure laterally surrounding at least a portion of the top contact, where the first electrical isolation structure extends substantially to a point along the second electrical isolation structure which is about half way between points of the second electrical isolation structure nearest to and farthest from the semiconductor substrate.

Another inventive aspect is a method of making a semiconductor device. The method includes providing a semiconductor substrate, and forming a memory cell on the semiconductor substrate, where forming the memory cell includes forming a bottom contact, forming a memory material on the bottom contact, forming a top contact on the memory material, and forming a first electrical isolation structure laterally surrounding at least one of the memory material, the bottom contact, and at least a portion of the top contact, where the first electrical isolation structure extends from the semiconductor substrate by a distance greater than a combined thickness of the memory material and the top contact.

In some embodiments, the method includes forming a second electrical isolation structure laterally surrounding at least a portion of the top contact, where the first electrical isolation structure has a first material, where the second electrical isolation structure has a second material, and the first and second materials are different.

In some embodiments, the method includes forming a second electrical isolation structure laterally surrounding at least a portion of the top contact, where the first electrical isolation structure has a first material, where the second electrical isolation structure has a second material, and the first and second materials are the same.

In some embodiments, the memory material includes a ferroelectric material.

In some embodiments, the method includes forming a second electrical isolation structure laterally surrounding at least a portion of the top contact, where the first electrical isolation structure extends substantially to a point along the second electrical isolation structure which is farthest from the semiconductor substrate.

In some embodiments, the method includes forming a second electrical isolation structure laterally surrounding at least a portion of the top contact, where the first electrical isolation structure extends substantially to a point along the second electrical isolation structure which is about half way between points of the second electrical isolation structure nearest to and farthest from the semiconductor substrate.

In the descriptions above and in the claims, phrases such as “at least one of” or “one or more of” may occur followed by a conjunctive list of elements or features. The term “and/or” may also occur in a list of two or more elements or features. Unless otherwise implicitly or explicitly contradicted by the context in which it used, such a phrase is intended to mean any of the listed elements or features individually or any of the recited elements or features in combination with any of the other recited elements or features. For example, the phrases “at least one of A and B;” “one or more of A and B;” and “A and/or B” are each intended to mean “A alone, B alone, or A and B together.” A similar interpretation is also intended for lists including three or more items. For example, the phrases “at least one of A, B, and C;” “one or more of A, B, and C;” and “A, B, and/or C” are each intended to mean “A alone, B alone, C alone, A and B together, A and C together, B and C together, or A and B and C together.” Use of the term “based on,” above and in the claims is intended to mean, “based at least in part on,” such that an unrecited feature or element is also permissible.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a semiconductor substrate; and
a memory cell on the semiconductor substrate, wherein the memory cell comprises:
a bottom contact,
a memory material on the bottom contact,
a top contact on the memory material,
a first electrical isolation structure laterally surrounding the top contact, and
a second electrical isolation structure, distinct from the first electrical isolation structure, laterally surrounding the memory material and the bottom contact.

2. The semiconductor device of claim 1, wherein the first electrical isolation structure has a first material, wherein the second electrical isolation structure has a second material, and the first and second materials are different.

3. The semiconductor device of claim 1, wherein the first electrical isolation structure has a first material, wherein the second electrical isolation structure has a second material, and the first and second materials are the same.

4. The semiconductor device of claim 1, wherein the memory material comprises a ferroelectric material.

5. The semiconductor device of claim 1, wherein the second electrical isolation structure extends substantially to a point along the first electrical isolation structure which is farthest from the semiconductor substrate.

6. The semiconductor device of claim 1, wherein the second electrical isolation structure extends substantially to a point along the first electrical isolation structure which is nearest to the semiconductor substrate.

7. The semiconductor device of claim 1, wherein the second electrical isolation structure extends substantially to a point along the first electrical isolation structure which is about half way between points of the first electrical isolation structure nearest to and farthest from the semiconductor substrate.

8. A semiconductor device, comprising:
a semiconductor substrate; and
a memory cell on the semiconductor substrate, wherein the memory cell comprises:
a bottom contact,
a memory material on the bottom contact,
a top contact on the memory material, and
a first electrical isolation structure laterally surrounding the memory material, the bottom contact, and at least a portion of the top contact.

9. The semiconductor device of claim 8, further comprising a second electrical isolation structure laterally surrounding at least a portion of the top contact, wherein the first electrical isolation structure has a first material, wherein the second electrical isolation structure has a second material, and the first and second materials are different.

10. The semiconductor device of claim 8, further comprising a second electrical isolation structure laterally surrounding at least a portion of the top contact, wherein the first electrical isolation structure has a first material, wherein the second electrical isolation structure has a second material, and the first and second materials are the same.

11. The semiconductor device of claim 8, wherein the memory material comprises a ferroelectric material.

12. The semiconductor device of claim 8, further comprising a second electrical isolation structure laterally surrounding at least a portion of the top contact, wherein the first electrical isolation structure extends substantially to a point along the second electrical isolation structure which is farthest from the semiconductor substrate.

13. The semiconductor device of claim 8, further comprising a second electrical isolation structure laterally surrounding at least a portion of the top contact, wherein the first electrical isolation structure extends substantially to a point along the second electrical isolation structure which is nearest to the semiconductor substrate.

14. The semiconductor device of claim 8, further comprising a second electrical isolation structure laterally surrounding at least a portion of the top contact, wherein the first electrical isolation structure extends substantially to a point along the second electrical isolation structure which is about half way between points of the second electrical isolation structure nearest to and farthest from the semiconductor substrate.

15. A method of making a semiconductor device, the method comprising:
providing a semiconductor substrate; and
forming a memory cell on the semiconductor substrate, wherein forming the memory cell comprises:
forming a bottom contact,
forming a memory material on the bottom contact,
forming a top contact on the memory material, and
forming a first electrical isolation structure laterally surrounding at least one of the memory material, the bottom contact, and at least a portion of the top contact, wherein the first electrical isolation structure extends from the semiconductor substrate by a distance greater than a combined thickness of the memory material and the top contact.

16. The method of claim 15, further comprising forming a second electrical isolation structure laterally surrounding at least a portion of the top contact, wherein the first electrical isolation structure has a first material, wherein the second electrical isolation structure has a second material, and the first and second materials are different.

17. The method of claim 15, further comprising forming a second electrical isolation structure laterally surrounding at least a portion of the top contact, wherein the first electrical isolation structure has a first material, wherein the second electrical isolation structure has a second material, and the first and second materials are the same.

18. The method of claim 15, wherein the memory material comprises a ferroelectric material.

19. The method of claim 15, further comprising forming a second electrical isolation structure laterally surrounding at least a portion of the top contact, wherein the first electrical isolation structure extends substantially to a point along the second electrical isolation structure which is farthest from the semiconductor substrate.

20. The method of claim 15, further comprising forming a second electrical isolation structure laterally surrounding at least a portion of the top contact, wherein the first electrical isolation structure extends substantially to a point along the second electrical isolation structure which is about half way between points of the second electrical isolation structure nearest to and farthest from the semiconductor substrate.
